(19) United States
(12) Patent Application Publication
(10) Pub. No.: US 2013/0068164 A1
(43) Pub. Date: Mar. 21, 2013

(54) HEATING UNIT AND FILM-FORMING APPARATUS

(71) Applicants: Naohisa IKEYA, Kanagawa (JP); Kunihiko Suzuki, Shizuoka (JP); Yuusuke Sato, Tokyo (JP)

(72) Inventors: Naohisa IKEYA, Kanagawa (JP); Kunihiko Suzuki, Shizuoka (JP); Yuusuke Sato, Tokyo (JP)

(21) Appl. No.: 13/611,493

(22) Filed: Sep. 12, 2012

(30) Foreign Application Priority Data
Sep. 20, 2011 (JP) 2011-204765

(51) Int. Cl. F27D 11/00; C23C 16/46

(52) U.S. Cl. 118/725; 219/385

(57) ABSTRACT

A heating unit and a film-forming apparatus comprising of a film-forming chamber, a heating unit for heating a substrate placed in the film-forming chamber, wherein the heating unit comprises of a heat source with a plane surfaced top, an electrode contacting electrically with the heat source, wherein the heat source has a ring-shape or a disk-shape that is formed by an individual, or plurality of heat source members. Wherein the heat source is comprised of a material selected from a group consisting of a carbon (C) material, a carbon material or a silicon carbide (SiC) material coated with silicon carbide (SiC), and a silicon carbide (SiC) material, and wherein the heat source has a ratio of the width (a) of the top portion direction to the thickness (X) of the side part (a/X) is 3 to 10.

### CROSS-REFERENCE TO THE RELATED APPLICATION

The entire disclosure of the Japanese Patent Application No. 2011-204765, filed on Sep. 20, 2011 including specification, claims, drawings, and summary, on which the Convention priority of the present application is based, are incorporated herein in its entirety.

### FIELD OF THE INVENTION

The present invention relates to a heating unit for heating a wafer, and a film-forming apparatus comprising the heating unit.

### BACKGROUND

A single wafer film-forming apparatus is often used to deposit a monocrystalline film such as a silicon film or the like, on a wafer, thereby forming an epitaxial wafer.

A film-forming apparatus is constructed so that a reaction gas will be supplied into a film-forming chamber in which a susceptor is located, a wafer is placed on the susceptor, and an epitaxial film will then be formed on the surface of the wafer by heating the back surface of the wafer. In an apparatus using a back heating system there is no heating source in the upper part of the apparatus. The reaction gas is supplied to the susceptor from a vertical direction, and then the gas flows in a laminar direction across the surface of the wafer to create a uniform epitaxial film.

In addition, the film-forming apparatus has a support portion for the susceptor, a rotating shaft (for rotating the susceptor on a rotational axis, extending downwardly through the through-holes in the bottom wall portion of the film-forming chamber), a rotating mechanism for rotating the rotating shaft, positioned in the lower section of the film-forming chamber.

By rotating the wafer during the film-forming process, a film of uniform thickness can be formed, see for example, Japanese Laid-Open Patent HEI 5-152207.

A resistance-heating unit, which heats by joule heat, is one example of a heat source that can be used in a film-forming apparatus. In the epitaxial growth process of Si (silicon) films, the temperature of the wafer is heated to around 1200° C. At that time, the temperature of the heating unit is higher than that of the wafer. As a result, components constituting the heating unit can deform and emit pollutants as a result of heating to this temperature.

In recent years, attention has been given to SiC (silicon carbide) instead of Si as a semiconductor material to be used in high-voltage power semiconductor devices. SiC is characterized in that its energy gap is two or three times larger, and its dielectric breakdown field is about one digit larger than that of a conventional semiconductor material such as Si (silicon) or GaAs (gallium arsenide).

SiC epitaxial film is formed by supplying H₂ (hydrogen) as a carrier gas, SiH₄ (monosilane) and C₃H₈ (propane) to a SIC wafer. Specifically, these gases are supplied into a film-forming chamber and then the gases flow as a substantially laminar flow on the upper surface of the SiC wafer placed on the heated susceptor. An epitaxial growth reaction occurs on the upper surface of the SiC wafer until the gases are exhausted. The temperature at which this reaction is performed is higher than that of an epitaxial growth reaction of Si film. Therefore, the temperature of the heater is higher than that used for epitaxial growth for Si film, approximately 2000° C.

However, the strength of a conventional heating unit is affected when the wafer is heated at high temperature by a heating unit in a film-forming apparatus, for example, to 2000° C. That is, it is a concern that the heating unit will deform as a result of the high temperature, especially the heat source. If the heating unit is deformed while the wafer is heated, the back surface of the wafer cannot be uniformly heated. As a result, an epitaxial film having a uniform quality cannot be formed on the surface of the wafer.

The present invention has been made to address the above-mentioned issues. That is, an object of the present invention is to provide a heating unit having a shape that maintains strength without deforming.

Furthermore, an object of the present invention is to provide a film-forming apparatus that can form a predetermined film on a wafer while the wafer is heated at a high temperature by a heating unit, the heater source member inside the heating unit having a shape that maintains strength.

Other challenges and advantages of the present invention are apparent from the following description.

### SUMMARY OF THE INVENTION

The present invention relates to a heater unit and a film-forming apparatus.

In a first embodiment of this invention, a heating unit comprising; a heat source with a plane surfaced top, an electrode contacting electrically with the heat source, wherein a top shape of the heat source is a ring-shape or a disk-shape with a pattern that is formed by a heat source member, having a top portion with a support portion in a sectional view of width direction, bent or tucked in length direction.

In a second embodiment of this invention, a film-forming apparatus comprising; a film-forming chamber, a heating unit for heating a substrate placed in the film-forming chamber, wherein a top shape of the heat source is a ring-shape or a disk-shape with a pattern that is formed by a heat source member, having a top portion with a support portion in a sectional view of width direction, bent or tucked in length direction.

### BRIEF DESCRIPTION OF THE DRAWINGS

FIG. 1a is a perspective view showing an open box shaped heat source member according to the present embodiment.

FIG. 1b is a perspective view showing a ‘T-shaped’ heat source member according to the present embodiment.

FIG. 1c is a perspective view showing a ‘L-shaped’ heat source member according to the present embodiment.

FIG. 1d is a perspective view showing a heat source member with two supports arranged at a 90 Degree angle from the top surface, as seen in the present embodiment.

FIG. 2a is a top view showing a structure of a heat source according to the present embodiment.

FIG. 2b is a cross-sectional view of a plurality of open box shaped heat source members.

FIG. 3a is a top view for explaining another example of the heat source of the heating unit according to the present embodiment.

FIG. 3b is a cross-sectional view along B-B′ of FIG. 3a.

FIG. 4 is a schematic cross-sectional view of a single wafer film-forming apparatus according to the present embodiment.

FIG. 5 is a schematic cross-sectional view for explaining another example of a film-forming apparatus in the present embodiment.

FIG. 6 is a perspective view showing the structure of a conventional heat source.

### DETAILED DESCRIPTION OF THE INVENTION

As mentioned above, a wafer is heated at high temperature by a heating unit in a film-forming apparatus, for example, at 2000° C. In this case, a heating unit that is capable of maintaining a very high temperature without deforming is required.

A resistance heating unit which heats by joule heat can comprise a heat source for heating and an electrode for applying voltage to the heat source. The heat of the resistance-heating unit can be controlled via the electrode by the voltage applied to the heat source. That is, the current in the heat source and the electrode, and the resistance of the heat source can control the heat of the resistance heater.

When the applied voltage in the heating unit is increased to increase the temperature, the current in the heat source is increased if the resistance of the heat source is constant. However, the current of the heating unit is often limited by the materials of the electrode, a wire connected with the electrode, for example. Therefore, it is hard to control the heat of the heating unit by the applied current.

For example, when an upper limit of the current in the heating unit is 300 A, from the perspective of the materials of the electrode, the wire etc, an upper limit of the applied voltage is limited to about 150V if the resistance of the heat source is 0.5Ω. Therefore, it is difficult to increase the heat by increasing the applied voltage to 150V or more.

When the current is limited like this, the applied voltage will be increased if the resistance of the heat source can be increased. For example, if the resistance of the heat source is 1Ω, the current in the heating unit is approximately 300 A, or less, when the applied voltage is to 300V. Therefore, the current is within the above-mentioned limits of the materials of the wire, and the heating unit will achieve the higher heat. Accordingly, a method of controlling the resistance of the heating unit, specifically the resistance of the heat source, is effective to increase the heat by the heating unit.

The shape of the heat source determines the resistance of the heat source.

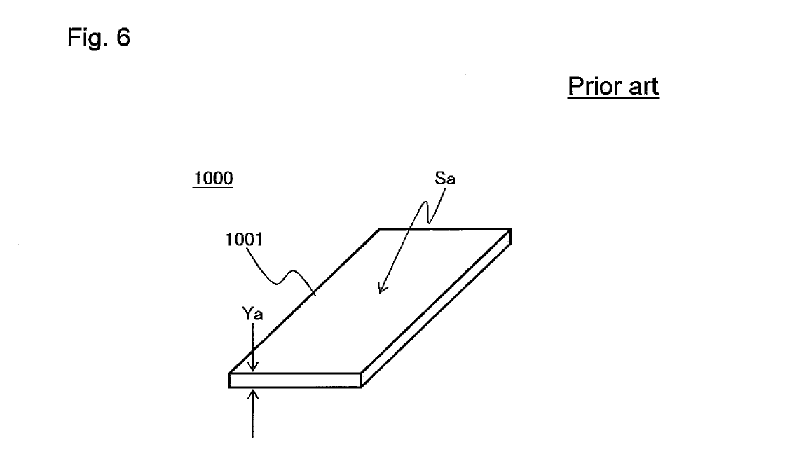

FIG. 6 is a perspective view showing the structure of a conventional heat source member.

As shown in FIG. 6, the conventional heat source 1000 is constructed based on a strip-like heat source member 1001 that has a rectangle section along the cross-sectional direction. The shape can determine the resistance of the heat source 1000. Specifically, the resistance of the heat source 1000 can be increased by making the thickness Ya of the heat source member 1001 thinner.

However, in the above-mentioned method, as the resistance of the heat source 1000 increases, the thickness Ya of the heat source member 1001 decreases. As a result, the heat source 1000 has less strength, even though the heat from the heating unit is increased, causing the heating unit to deform.

The heat source 1000 can be provided below the wafer in the film-forming apparatus. In this case, the heat source 1000 comprising the heat source member 1001 is preferably supported on both sides to position the top surface Sa of the heat source member 1001 to face the back surface of the wafer. As the heat source is used under high temperature conditions the heat source member can be affected and incur stress, as a result the heat source 1000 often warps and deforms causing the heat source 1000 to move in a downward direction, when the thickness Ya of the heat source member 1001 cannot maintain strength.

The distance between the wafer and the heat source in the film-forming apparatus is optimized so that the wafer can be heated under desired conditions. If the heat source deforms, the distance between the wafer and the heat source will be out of the design value, and then the wafer cannot be heated under the preferred condition. Furthermore, the heating unit cannot uniformly heat the back surface of the wafer, as a result, an epitaxial film having a uniform quality cannot be formed on the wafer.

In view of the problems of a conventional heating unit, a heating unit according to the present embodiment comprises a heat source having a shape that can attain sufficient strength. Moreover, the resistance of the heating unit can be easier to control as a result of the shape of the heat source.

Hereinafter, the present embodiment will be described in detail referring to the drawings. For ease of convenience each component in these drawings uses the same symbol throughout. As a result a duplicated explanation of components is omitted.

### Embodiment 1

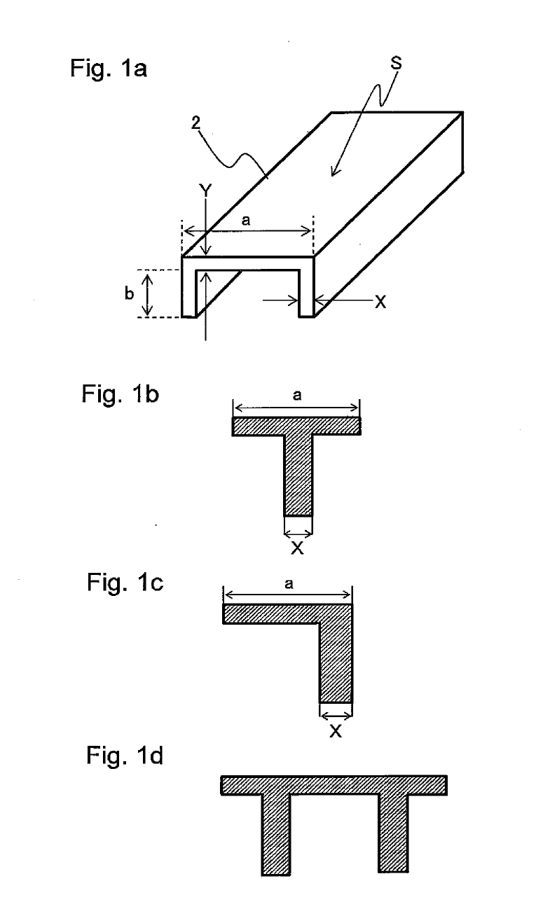

FIG. 1a is a perspective view showing a structure of a heat source member according to the present embodiment.

The heat source 1, as shown in FIG. 1a, comprises a heat source member 2 having a cross-sectional shape formed in an open box shape continuing along the length of the member. This shape is three sided, wherein the middle side is the top portion, and wherein the cross-sectional shape of width direction is box shaped, yet without a fourth side, thus allowing the member to be open.

The middle side of the open box-shaped heat source member may be located so as to be closest to the substrate.

The sides as the support portion of the heat source member may also be positioned in a different location, for example closer to the centre of the top portion, as seen in FIG. 1d, yet still maintain strength.

The heat source member may also be T-shaped in sectional view of width direction, as seen in FIG. 1b, wherein the top of the T-shape is the top portion and the bottom is the support portion.

The heat source member may also be L-shaped in sectional view of width direction, as seen in FIG. 1c, wherein the top of the L-shape is the top portion and the bottom is the support portion.

Further, the heat source member may also consist of a two-sided shape wherein the shapes are set at a 90-degree angle to each other. One side acts as the support, the other side acts as the top surface.

The heat source member is not limited to the above-mentioned construction and may include a top portion and a support portion wherein the support portion is positioned in an alternative location to the above-mentioned.

In any heat source member construction consisting of only one support as opposed to an open box-shaped heat source member, the ratio required to determine the sizing of ‘a’ and ‘X’ as seen in FIG. 1c, wherein ‘a’ is the width of the top portion and ‘X’ is the width of the supporting portion, is: a/X=1.5˜5.

This ratio is preferably in the range of: a/X=2˜4.

In regards to the heat source member 2 according to the present embodiment, as shown in FIG. 1a, the relationship between thickness ‘Y’ of an upper part, thickness ‘X’ of a side part, width ‘a’ of the top portion, and height ‘b’ of the side part is optimized in consideration of the electrical properties. Furthermore, this relationship is preferred to maintain strength of the heat source 1, as the top portion ‘S’ of the heat source member 2 faces the back surface of the wafer in the film-forming apparatus. For example, the thickness Y of the top part can be the same as the thickness X of the side part. The ratio of the width a of the top portion to the thickness X of the side part (a/X) is preferably in the ratio of 3 to 10, further preferably in the ratio of 4 to 8. According to the above-mentioned structure, the heat source 1 has a preferred resistance and an effective shape for maintaining strength.

The heat source member can be formed from a material selected from a group consisting of a carbon (C) material, a carbon material or a silicon carbide (SiC) material coated with silicon carbide (SiC), or a silicon carbide (SiC) material.

The heat source member 2 of the heat source 1 according to the present embodiment has a shape that can maintain strength. The heat source 1 can be provided below the wafer so that the upper surface S of the heat source member 2 faces the back surface of the wafer. The heat source 1 provides heat to the back surface of the wafer, and during this process the possibility of the heat source member 2 warping or deforming is minimized. As a result, the wafer can be heated under the desired condition in the film-forming apparatus and the back surface of the wafer can be uniformly heated via the heat source member 2 of the heating unit of the present embodiment.

The heat source member 2 of the heating unit of the present embodiment has an open box-shaped section allowing the member to maintain strength. Therefore it can make the thickness Y of the upper part of the heat source member 2 thinner than the heat source member 1001 of the heat source 1000 of the conventional heating unit in FIG. 6. According to the heating unit of the present embodiment, the resistance of the heat source can be higher than the conventional heating unit when the shape of the heat source 1 determines the resistance of the heat source member. As a result, the heating unit of the present embodiment can heat at a higher temperature; for example, it can be used in a film-forming apparatus that requires heat at a temperature of 2000° C.

The heat source member 2 of the heating unit of the present embodiment has an open box-shaped section allowing the member to maintain strength. The heat source member 2 can be used to create a heat source formed in a variety of shapes. Also, a plurality of heat source members 2 as shown in FIG. 1a can be combined with each other, and thereby form a selection of diverse shapes. For example, the heat source member 2 can be bent or tucked, while the heat source 1 consists of a plane shaped top-surface. As a specific example the heat source 1 can be ring-shaped or disk-shaped.

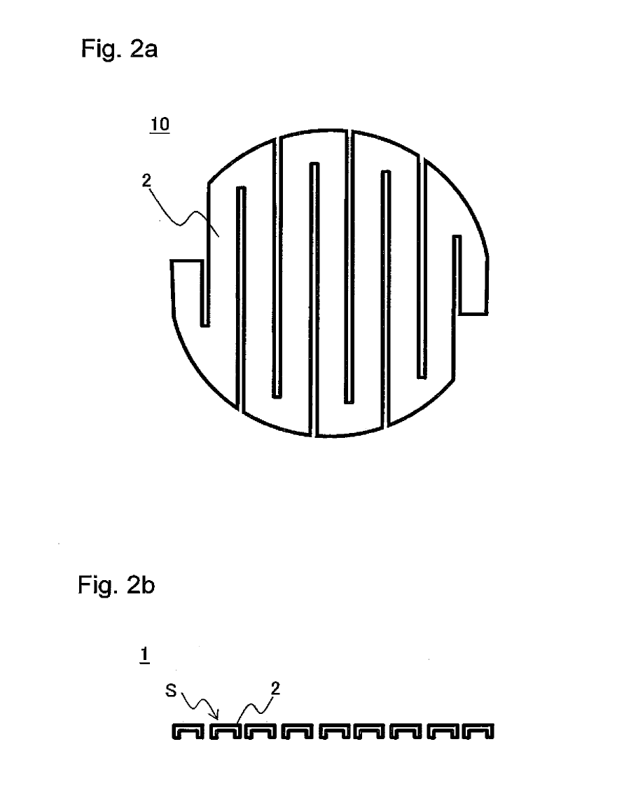

FIG. 2a is a perspective views showing an example of a heat source according to the present embodiment. FIG. 2a is a top view showing a structure of a heat source according to the present embodiment.

The heat source 10 in FIG. 2a includes the heat source member 2 that consists of an open box-shaped cross section continuing along as a channel, as shown in FIG. 1a. The heat source member 2 is bent and the heat source 10 is disk-shaped with a plane shaped top-surface. Each end of the heat source 10 are electricity connected with electrodes (not shown), and thereby the heating unit can be constructed as such in the present embodiment. The heat source 1, as shown in FIG. 2b, comprises a plurality of open box-shaped heat source member 2. As mentioned above, the heat source member 2 comprising the heat source 10 and heat source 1 can be formed from a material selected from a group consisting of a carbon (C) material, a carbon material or a silicon carbide (SiC) material coated with silicon carbide (SiC), and a silicon carbide (SiC) material. The heating unit having the heat source 10 or heat source 1 consisting of a plane shaped top part according to the present embodiment can be suitably used in a film-forming apparatus to heat a wafer.

In FIG. 2b, the heat source 1 is made up of a plurality of open box-shaped heat source members 2, and a surface of the heat source 1 is made up of the top surface S of the heat source members 2, thereby, the surface of the heat source 1 is a plane surface. Therefore, the distance between a wafer and the heating unit can be optimized to an equal distance apart on all points between the wafer and the heating unit according to the present embodiment.

As mentioned above, the heat source 10 comprises the open box-shaped section heat source member 2 as a basic structure, and the heat source 10 has a shape that can maintain strength. Therefore, the heat source 10 can be applied to the film-forming apparatus, and is provided below the wafer so that the top surface of the heat source 10 is facing the back surface of the wafer. As a result, the possibility of the heat source 10 warping or deforming will be decreased, and the heating unit will be prevented from being transformed. As a result, the wafer can be heated under the desired conditions in the film-forming apparatus and the back surface of the wafer can be uniformly heated according to the heating unit of the present embodiment.

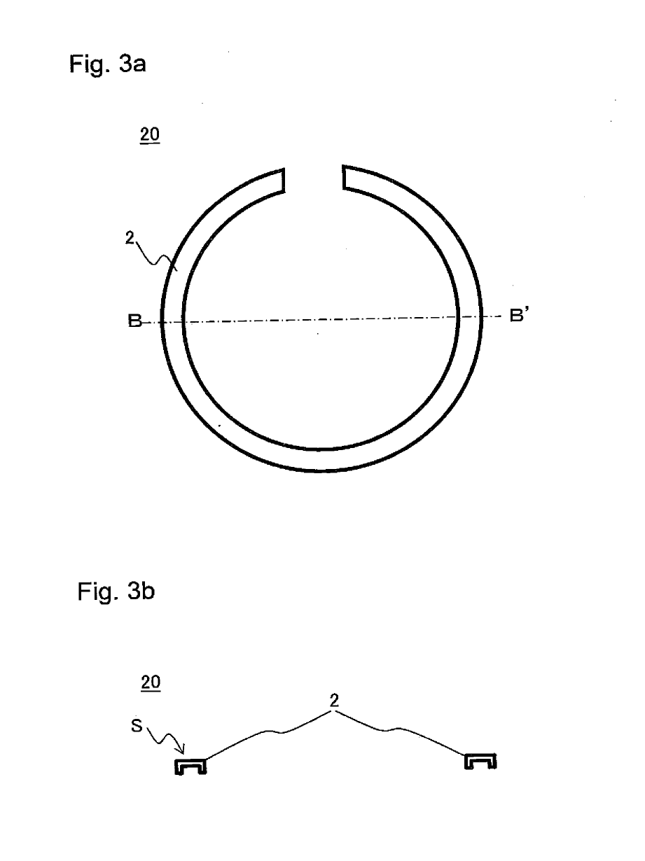

FIG. 3a and FIG. 3b show another example of the heat source 20 according to the present embodiment. FIG. 3a is a top view for explaining another example of the heat source 20 according to the present embodiment. FIG. 3b is a cross-sectional view along B-B′ of FIG. 3a.

In the heat source 20 in FIG. 3a, the basic structure is the heat source member 2 with a plane shaped top portion, as in FIG. 1a, the heat source 20 is ring-shaped, having a gap in the plane shaped top portion, that is, the ring is not fully enclosed. Each end of the heat source 20 is electrically connected with an electrode (not shown), and thereby a heating unit as another example in the present embodiment is formed.

As shown in FIG. 3b, the heat source 20 is composed so that it has an open box-shaped section, and thereby the heat source 20 has a shape that can maintain strength. As mentioned above, the heat source member 2 comprising the heat source 20 can be formed from a material selected from a group consisting of: a carbon (C) material, a carbon material or a silicon carbide (SiC) material coated with silicon carbide (SiC), and a silicon carbide (SiC) material. The heating unit having the heat source 20 with a plane shaped top portion according to the present embodiment can be suitably applied in a film-forming apparatus to heat a wafer.

In FIG. 3a and FIG. 3b, the heat source 20 is made up a plurality of open box-shaped heat source members 2, and a surface of the heat source 20 is made up of the top surface S of the heat source members 2, the surface of the heat source 10 is a plane surface. Therefore, the correct distance between a wafer and the heat source 20 can be maintained with high precision by using the heating unit according to the present embodiment.

Next, the apparatus using the heating unit according to the present embodiment will be described. As mentioned above, the heat source 20 is comprised of the open box-shaped heat source member 2, and thereby the heat source 20 has a shape that can maintain strength. Therefore, the heat source 20 can be utilized in a film-forming apparatus, provided below the wafer so that the top surface of the heat source 20 faces the back surface of the wafer. Thereby, the possibility of the heat source 20 warping or deforming will be prevented. As a result, the wafer can be heated under the desired condition in the film-forming apparatus and the back surface of the wafer can be uniformly heated according to the heating unit of the present embodiment.

The film-forming apparatus comprising the heating unit according to the present embodiment, will be described in detail with reference to the accompanying drawings.

### Embodiment 2

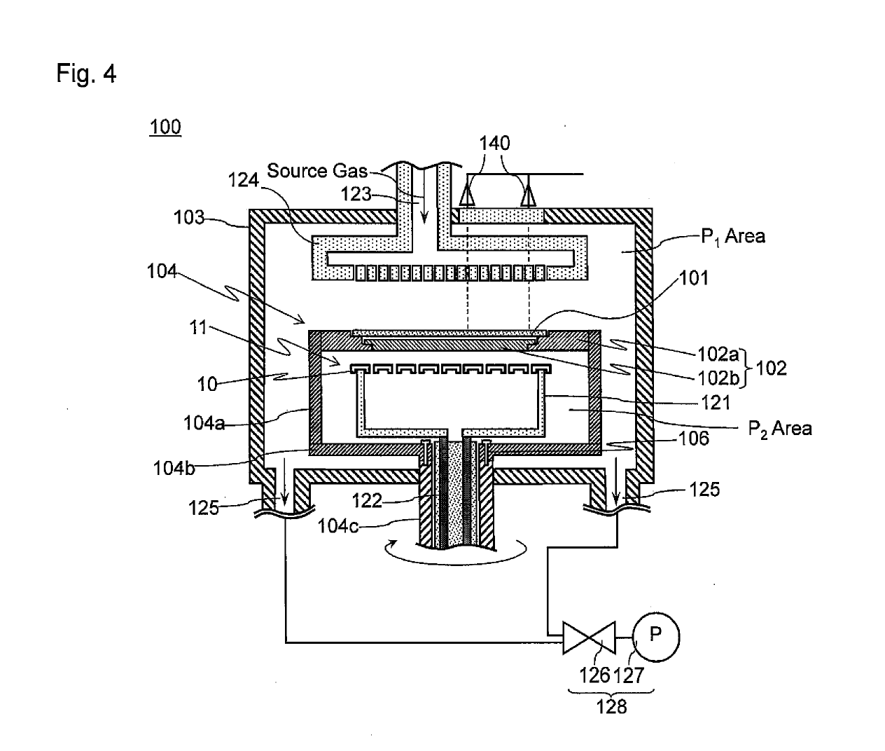

FIG. 4 is a schematic cross-sectional view of a film-forming apparatus according to the present embodiment. In this preferred embodiment, the film-forming apparatus 100 is designed to deposit a SiC (silicon carbide) film on the top surface of a substrate. The substrate may be, as one example, a SiC wafer, however, the present embodiment is not limited to this example. It is also possible to use other substrates formed of different materials, for example, a silicon wafer. Further, the film-forming apparatus in the present embodiment can also be applied to epitaxial growth of Si (silicon film).

The film-forming apparatus 100 includes a chamber 103 as a film-forming chamber.

The gas supply portion 123, used for supplying a source gas for forming the crystalline film on the surface of the heated SiC wafer 101, is provided in the upper part of the chamber 103. The gas supply portion 123 connects with a shower plate 124 consisting of a plurality of through-holes for distributing the source gas. The shower plate 124 faces the surface of the SiC wafer 101, and thereby the source gas can be supplied to the surface of the SiC wafer 101.

The source gas used can be, for example, monosilanes (SiH₄) and propane (C₃H₈). These are mixed with hydrogen gas used as a carrier gas, and are introduced from the gas supply portion 123 into the chamber 103. In this case, disilane (SiH₅), monochlorosilanes (SiH₃Cl), dichlorosilane (SiH₂Cl₂), torichlorosilane (SiHCl₃) or tetrachlorosilane (SiCl₄) can be used instead of monosilane (SiH₄).

A plurality of discharge portions 125 for discharging the source gas after reaction, are provided at the bottom of the chamber 103. The discharge portion 125 is connected with a discharge system 128 consisting of a control valve 126 and a vacuum pump 127. The discharge system 128 is controlled by a control system (not shown), and thereby the pressure in the chamber 103 will be controlled to be at the predetermined pressure.

A susceptor 102 is provided on a rotating section 104 in the chamber 103. The susceptor 102 comprises a first susceptor part 102a for supporting the outer peripheral of the SiC wafer 101, and a second susceptor part 102b which is designed to be a close fit in the opening of the first susceptor part 102a. Since the first susceptor 102a and the second susceptor part 102b are placed under high temperatures, high-purity SiC, for example, is used for the susceptor material.

The first susceptor part 102a and the second susceptor part 102b may be a structure in which they are formed as one part. However, it is preferred to provide the second susceptor part 102b so that the SiC wafer 101 can be prevented from being contaminated by contaminants developed in the heating unit 11 and the rotating section 104.

The rotating section 104 includes a rotating cylinder 104a, a rotating base 104b and a rotating shaft 104c. The rotating cylinder 104a for supporting the susceptor 102 is fixed on the rotating base 104b. The susceptor 102 is provided on the rotating cylinder 104a. The heating unit 11 is provided in the rotating cylinder 104a. The rotating base 104b is connected with the rotating shaft 104c via fixing screws 106.

The rotating shaft 104c is extended out of the chamber 103, and is connected with a rotating system (not shown). The rotating shaft 104c is rotated, rotating the susceptor 102 via the rotating base 104b and the rotating cylinder 104a, and as a result the SiC wafer 101 supported by the susceptor 102 will be rotated. The SiC wafer 101 is rotated during the film-forming process, and a film having a uniform thickness can be formed. It is preferred that the rotating cylinder 104a is rotated around an axis passing through the center of the SiC wafer 101 and being at right angles to the SiC wafer 101.

In FIG. 4, the rotating cylinder 104a has an opening in the upper part, but the space (hereinafter P2 area) is formed when the upper part is covered with the susceptor 102. If the second susceptor part 102b is not provided, P2 area is formed when the SiC wafer 101 is supported by the first susceptor part 102a. P1 area and P2 area are substantially divided by the susceptor 102.

The heating unit 11 for heating the back surface of the SiC wafer 101, is provided in the area P2. The heating unit 11 includes the above-mentioned heat source 10 as a heat source with a plane shaped top surface, and the electrode 122 according to embodiment 1. The heat source 10 is supported by an arm-shaped busbar 121 in the heating unit 11. The busbar 121 is connected with the electrode 122 at the opposite side of the side of the busbar that supports the heat source 10. That is, the heat source 10 is electrically connected with the electrode 122 via the busbar 121 for supporting the heat source 10 in the heating unit 11.

The material comprising the heat source 10 can be selected from a group consisting of a carbon (C) material, a carbon material or a silicon carbide (SiC) material coated with silicon carbide (SiC), and a silicon carbide (SiC) material. In the present embodiment, it is preferable to use a carbon material or a silicon carbide (SiC) material coated with silicon carbide (SiC), or a silicon carbide (SiC) material.

The heat source 10 is comprised of the open box-shaped section heat source member 2 as shown in FIG. 1a, and thereby the heat source 10 has a shape that can maintain strength. Therefore if the heat source 10 is provided below the SiC wafer 101 in the film-forming apparatus 100, the possibility of the heat source 10 warping or deforming will be decreased and the heating unit will be prevented from being transformed. As a result, the SiC wafer 101 can be heated under the desired condition in the film-forming apparatus 100 and the back surface of the SiC wafer 101 can be uniformly heated by the heating unit 11 of the present embodiment.

The busbar 121 for supporting the heat source 10, is made from materials having electrical conductivity and high heat resistance, for example, a carbon material coated with silicon carbide (SiC). The electrode 122 is made from molybdenum (Mo). Electricity is conducted from electrode 122 to the heat source 10 via the busbar 121 used for supporting the heating unit 11. Specifically, electricity is conducted from the electrode 122 to the heat source 10, and thereby the heat source 10 is heated and the temperature is increased.

A radiation thermometer 140 provided in the upper part of the chamber 103 measures the surface temperature of the SiC wafer 101, changed as a result of the heating process. The thermometer 140 is part of a temperature-measuring unit of the present invention. It is preferable that the shower plate 124 be formed of quartz, because the use of quartz prevents it affecting the temperature measurement of the radiation thermometer 140. After temperature measurement the data is sent to a control system (not shown) and then fed back to an output control device of the heating unit 11. Thereby, the SiC wafer 101 can be heated at a desired temperature

In the present embodiment, the SiC wafer 101 can be heated by an in-heater and an out-heater. In this case, the out-heater mainly heats the outer periphery of the susceptor 102, and the in-heater can be provided below the out-heater for mainly heating the parts other than the outer periphery of the susceptor 102.

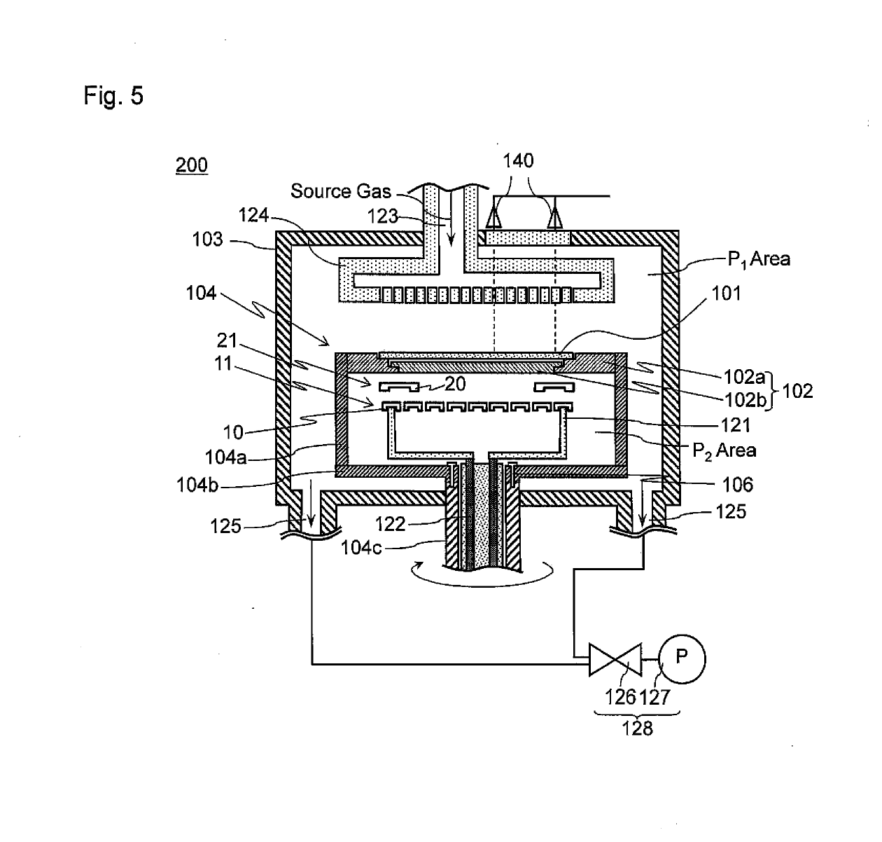

FIG. 5 is a schematic cross-sectional view for explaining another example of a film-forming apparatus in the present embodiment.

In the film-forming apparatus 200 in FIG. 5, the SiC wafer 101 is heated by an in-heater and an out-heater. The in-heater can be used as the heating unit 11 according to the present embodiment as well as the film-forming apparatus 100 in FIG. 4. The out-heater can be used as the heating unit 21 having the heat source 20 with a plane shaped top surface as the heat source 20 according to the first embodiment in FIG. 3. Other main components in the film-forming apparatus 200 can be the same as the above-mentioned film-forming apparatus 100.

The structure of the heating unit 21 is similar to the above-mentioned heating unit 11 except for the shape of the heat source 20. The heat source 20 with a plane shaped top surface is electrically connected with the electrode 122 via a bulbar (not shown) for supporting the heat source 20. The material comprising the heat source 20 can be selected from a group consisting of a carbon (C) material, a carbon material or a silicon carbide (SiC) material coated with silicon carbide (SiC), and a silicon carbide (SiC) material. In the present embodiment, it is preferable to use a carbon material or a silicon carbide (SiC) material coated with silicon carbide (SiC), or a silicon carbide (SiC) material.

Since the film-forming apparatus 200 includes the above-mentioned structure, it can uniformly heat the back surface of the SiC wafer 101, and thereby the uniformity of the temperature distribution will be improved. Both the heat source 10 of the heating unit 11 and the heat source 20 of the heating unit 21 consist of an open box-shaped section heat source member 2, and thereby has a shape that maintains strength. Therefore, if the heat source 10 and the heat source 20 are provided below the SiC wafer 101 in the film-forming apparatus 200, the possibility that they will warp or deform is decreased and the heating unit will be prevented from being deformed. As a result, the SiC wafer 101 can be heated under the desired condition in the film-forming apparatus 200.

Features and advantages of the present invention can be summarized as follows.

In the first embodiment in the present invention a heating unit is provided having a shape so that a heat source can maintain strength and be prevented from being deformed when it is used in a film-forming apparatus.

The second embodiment in the present invention provides a film-forming apparatus, including a heater source of a shape so that a heat source can maintain strength, for forming a predetermined film on a substrate while the substrate is heated at high temperature.

The present invention is not limited to the embodiments described above and can be implemented in various ways without departing from the spirit of the invention.

For example, the above embodiment has been described as an example of a film-forming process while rotating the wafer in a film-forming chamber, the present invention is not limited to this. The film-forming apparatus of the present invention may be deposited on the wafer while stationary and not rotating.

Furthermore, the heating unit as described above may also include a construction, wherein the heat source has a ring-shape or a disk-shape that is formed by a plurality of an open box-shaped section heat source member and a plain section heat source member.

In addition to the above embodiments, an epitaxial growth system cited as an example of a film-forming apparatus for forming SiC film in the present invention is not limited to this. Reaction gas supplied into the film-forming chamber for forming a film on its surface while heating the wafer, can also be applied to other apparatus like a CVD (Chemical Vapor Deposition) film-forming apparatus, and to form other epitaxial films.

1. A heating unit comprising:
a heat source with a plane surfaced top;
an electrode contacting electrically with the heat source,
wherein a top shape of the heat source is a ring-shape or a disk-shape with a pattern that is formed by a heat source member, having a top portion with a support portion in a sectional view of width direction, bent or tucked in length direction.

2. The heating unit according to claim 1, wherein the heat source member has either an open box-shaped, T-shaped, or L-shaped in the sectional view of width direction.

3. The heating unit according to claim 1, wherein the heat source member is comprised of a material selected from a group consisting of a carbon (C) material, a carbon material or a silicon carbide (SiC) material coated with silicon carbide (SiC), and a silicon carbide (SiC) material.

4. The heating unit according to claim 1, wherein the ratio of the width (a) of the top portion to the thickness (x) of the supporting portion (a/X) of the heat source member consisting of two supporting portions, is a ratio of 3 to 10.

5. The heating unit according to claim 1, wherein the ratio of the width (a) of the top portion to the thickness (x) of the supporting portion (a/X) of the heat source member consisting of a single supporting portion, is a ratio of 1.5 to 5.

6. The heating unit according to claim 5, wherein the ratio of the width (a) of the top portion to the thickness (x) of the supporting portion (a/X) of the heat source member consisting of a single supporting portion, is a ratio of 2 to 4.

7. A film-forming apparatus comprising:
a film-forming chamber;
a heating unit for heating a substrate placed in the film-forming chamber;
wherein the heating unit comprises of a heat source with a plane surfaced top;
an electrode contacting electrically with the heat source;
wherein a top shape of the heat source is a ring-shape or a disk-shape with a pattern that is formed by a heat source member, having a top portion with a support portion in a sectional view of width direction, bent or tucked in length direction.

8. The film-forming apparatus according to claim 7, wherein the heat source member has either an open box-shaped, T-shaped, or L-shaped in the sectional view of width direction.

9. The film-forming apparatus according to claim 7, wherein the heat source is comprised of a material selected from a group consisting of a carbon (C) material, a carbon material or a silicon carbide (SiC) material coated with silicon carbide (SiC), and a silicon carbide (SiC) material.

10. The film-forming apparatus according to claim 7, wherein the ratio of the width (a) of the top portion to the thickness (X) of the supporting portion (a/X) of the heat source member consisting of two supporting portions, is a ratio of 3 to 10.

11. The film-forming apparatus according to claim 7, wherein the ratio of the width (a) of the top portion to the thickness (X) of the supporting portion (a/X) of the heat source member consisting of a single supporting portion, is a ratio of 1.5 to 5.

12. The film-forming apparatus according to claim 11, wherein the ratio of the width (a) of the top portion to the thickness (X) of the supporting portion (a/X) of the heat source member consisting of a single supporting portion, is a ratio of 2 to 4.

13. The film-forming apparatus according to claim 7,
wherein the heating unit has a first heater for heating the substrate, and a second heater for heating the periphery of the substrate;
wherein the heat source of the first heater is a disk-shape and
wherein the heat source of the second heater is a ring-shape.
